(19) United States
(12) Patent Application Publication
(10) Pub. No.: US 2026/0123382 A1
(43) Pub. Date: Apr. 30, 2026

(54) CONDUCTIVE VIA WITH REDUCED RESISTANCE

(71) Applicant: Taiwan Semiconductor Manufacturing Company, Ltd, Hsinchu (TW)

(72) Inventors: Jen-Pan WANG, Tainan (TW); Hsiao-Chiu HSU, Hsinchu (TW)

(73) Assignee: Taiwan Semiconductor Manufacturing Company, Ltd., Hsinchu (TW)

(21) Appl. No.: 18/932,196

(22) Filed: Oct. 30, 2024

(51) Int. Cl. H01L 23/522; H01L 21/3213; H01L 21/768; H01L 23/528; H01L 23/532

(52) U.S. Cl. CPC H10W 20/42; H10P 50/264; H10W 20/057; H10W 20/076; H10W 20/435; H10W 20/425; H10W 20/4421

(57) ABSTRACT

This disclosure is directed to an interconnect structure of a semiconductor device and a method of forming the interconnect structure. The interconnect structure includes a first metal line, a second metal line on the first metal line, and a conductive via electrically coupling the first and second metal lines. The conductive via includes a protrusion laterally and vertically extending into the first metal line to reduce a contact resistance between the conductive via and the first metal line. The method includes forming the first metal line and a dielectric layer on the first metal line, forming an opening in the dielectric layer to expose the first metal line, and laterally recessing the first metal line in the opening. The method further includes depositing a conductive material in the opening to form the conductive via and the second metal line.

### BACKGROUND

The semiconductor integrated circuit (IC) industry has experienced exponential growth. Technological advances in IC materials and design have produced generations of ICs, where each generation has smaller and more complex circuits than the previous generation. In the course of IC evolution, there has been increasing demand for higher storage capacity, faster processing systems, higher performance, and lower costs. To meet these demands, functional density (e.g., the number of interconnected devices per chip area) has generally increased while geometry size (e.g., the smallest component or line that can be created using a fabrication process) has decreased.

Accordingly, critical dimensions of interconnect structures are getting smaller to facilitate connecting more devices within limited space.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is a cross-sectional view of a semiconductor device including multiple layers of interconnect structure, in accordance with some embodiments.

FIGS. 2A-2C are cross-sectional views of an interconnect structure in a zoomed-in region of FIG. 1, in accordance with some embodiments.

FIGS. 3A-3C are cross-sectional views of a zoomed-in region of FIGS. 2A-2C, in accordance with some embodiments.

FIGS. 4A and 4B are cross-sectional views of an interconnect structure, in accordance with some embodiments.

FIGS. 5A-5C are flowcharts of methods of forming an interconnect structure, in accordance with some embodiments.

FIGS. 6-17 are cross-sectional views of intermediate structures during the fabrication of an interconnect structure, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

An integrated circuit includes multiple semiconductor devices that are electrically connected together by interconnect structures. The interconnect structures include, for example, metal lines which provide routing between the semiconductor devices in directions parallel to a top surface of a substrate of the integrated circuit. Metal lines on different layers and levels of the integrated circuits can be electrically connected one another by conductive vias that extend vertically through dielectric layers between the metal lines on the different layers and levels. A conductive via can be formed to have its bottom surface electrically connected to a first metal line in a first interconnect level below the conductive via and to have its top surface electrically connected to a second metal line in a second interconnect level above the conductive via. Barrier layers can be formed on surfaces of the conductive vias to avoid diffusion or migration of conductive materials from the conductive vias into the surrounding dielectric layers.

As semiconductor devices continue scaling down, critical dimensions of the conductive via are getting smaller to facilitate connecting more semiconductor devices within limited space. Accordingly, the formation of the conductive via becomes more challenging, as higher aspect ratio (e.g., a ratio of a depth to a width) of the conductive via increases its resistance, affecting the conductive performance of the conductive via for effective coupling between the metal lines. For example, a barrier layer can include a portion between the conductive via and a metal line below the conductive via. Since the barrier layer is made of materials with a resistivity higher than the conductive material of the conductive via, the portion of the barrier layer with a reduced size can be a bottleneck of the conductive performance of the conductive via. Even if the barrier layer can be made such that the conductive via and the metal line have a direct contact without the presence of the barrier layer in between, the contact resistance of the direct contact with a reduced size can be a limitation to the conductive performance of the conductive via, due to the structural discontinuity of the conductive materials on both sides of the boundary between the conductive via and the metal line (e.g. different grain sizes on the side of the conductive via and the side of the metal line resulting in conductivity mismatch that enhances the scattering of charge carriers).

To overcome the challenges mentioned above, the embodiments described herein are directed to an interconnect structure of a semiconductor device and a method of forming the interconnect structure. In some embodiments, the interconnect structure can include a first metal line, a second metal line on the first metal line, and a conductive via electrically coupling the first and second metal lines. The conductive via can include a protrusion vertically and laterally extending into the first metal line to increase a contact area between the conductive via and the first metal line, such that a contact resistance between the conductive via and the first metal line can be reduced. The method can include forming the first metal line and a dielectric layer on the first metal line, forming an opening in the dielectric layer to expose the first metal line, and laterally recessing the first metal line to extend the opening into the first metal line. The method can further include depositing a conductive material in the opening to form the conductive via and the second metal line.

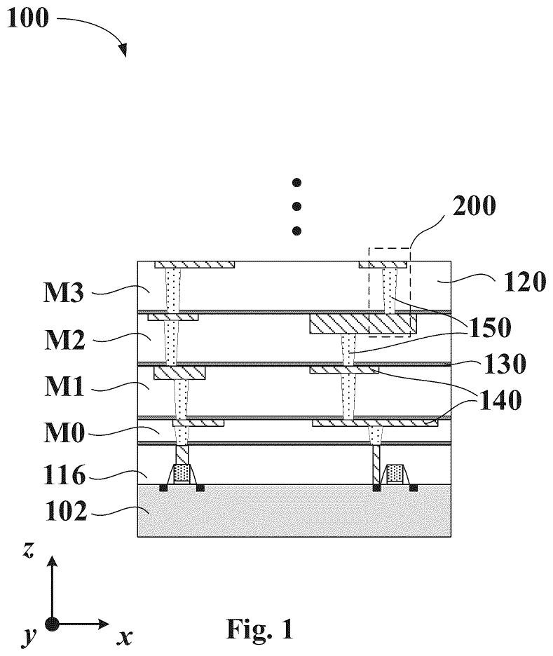

A semiconductor device 100 is shown with a cross-sectional view in FIG. 1, according to some embodiments. Semiconductor device 100 can include a substrate 102, a device layer 116 disposed on substrate 102, and a number of interconnect layers disposed on device layer 116. Semiconductor device 100 can be included in a microprocessor, memory cell, or other integrated circuit (IC).

Referring to FIG. 1, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Device layer 116 can include transistors disposed on substrate 102. The transistors can include metal oxide semiconductor field effect transistors (MOSFETs), such as planar MOSFETS, fin field effect transistors (FinFETs), complementary fin field effect transistors (CFETs), gate-all-around field effect transistors (GAA FETs) and/or vertical fin field effect transistors (VFETs). Device layer 116 can further include contact structures to the transistors, such as gate contact structures and source/drain contact structures. Device layer 116 can also include other electronic elements, such as resistors, capacitors, inductors, and the contact structures in contact with these electronic elements.

Referring to FIG. 1, the interconnect layers disposed on device layer 116 can include interconnect layers M0, M1, M2, M3, etc. Although there are 4 interconnect layers shown in FIG. 1 as an example, the number of the interconnect layers can be any integer greater than 1. For example, semiconductor device 100 can include 2, 4, 8, 12, 16, 24, or 32 interconnect layers. In some embodiments, the interconnect layers can be formed in a back-end-of-line (BEOL) process. Each interconnect layer can include an etch stop layer 130 and a dielectric layer 120 on etch stop layer 130. Each interconnect layer can further include metal lines 140 in dielectric layer 120 and conductive vias 150 through etch stop layer 120 and dielectric layer 120. Conductive vias 150 can electrically couple metal lines 140 with conductive elements below and/or above each interconnect layer. For example, among the interconnect layers, interconnect layer M0 is closest to device layer 116, and conductive vias 150 in interconnect layer M0 can electrically couple metal lines 140 of interconnect layer M0 with contact structures in device layer 116. In another example, conductive vias 150 in interconnect layer M2 can electrically couple metal lines 140 of interconnect layer M2 with metal lines 140 of interconnect layer M1 and/or M3. Etch stop layer 130 and dielectric layer 120 can include low-k dielectric materials, such as silicon oxide (SiₓO_{y}), silicon nitride (SiₓN_{y}), silicon oxy-carbon-nitride (SiₓO_{y}C_{z}Nᵤ), silicon carbon-nitride (SiₓC_{y}N_{z}), silicon oxy-nitride (SiₓO_{y}N_{z}), silicon carbide (SiₓC_{y}), aluminum nitride (AlₓN_{y}), aluminum oxide (AlₓO_{y}), or aluminum oxy-nitride (AlₓO_{y}N_{z}). Metal lines 140 and conductive vias 150 can include any suitable conductive materials, such as titanium, aluminum, copper, tungsten, tantalum, nickel, ruthenium, other suitable metals, and/or a combination thereof.

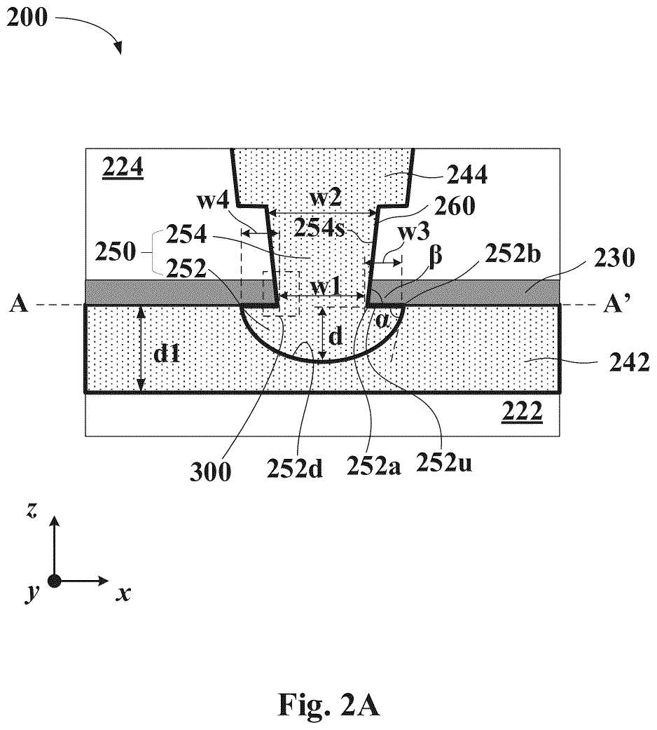

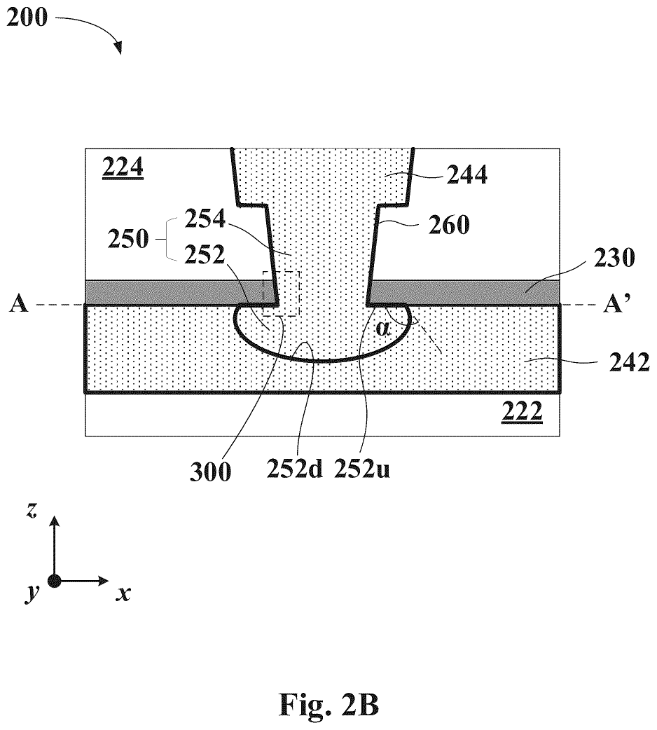

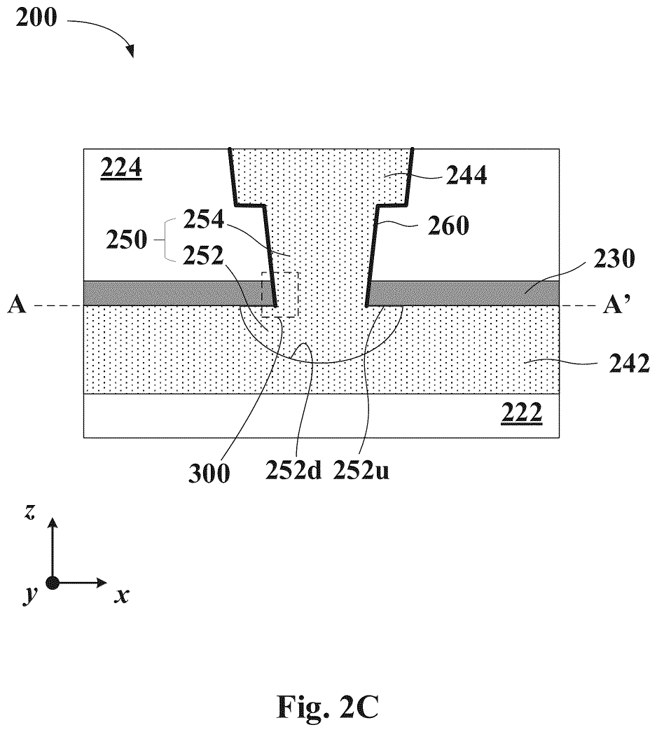

FIGS. 2A-2C illustrate cross-sectional views of a structure 200, which is a zoomed-in portion of FIG. 1 around a region of the interconnect layers. The discussion of elements in FIG. 1 with the same or similar annotations applies to FIGS. 2A-2C, unless mentioned otherwise.

Referring to FIG. 2A, structure 200 can include a dielectric layer 222 and a metal line 242 on dielectric layer 222. In some embodiments, dielectric layer 222 and metal line 242 can be portions of a first interconnect layer (e.g. one of interconnect layers M0, M1, M2, M3, etc, as shown in FIG. 1). Structure 200 can further include a dielectric layer 224 and a metal line 244 in dielectric layer 224. Dielectric layer 224 and metal line 244 are disposed on dielectric layer 222 and metal line 242 and can be portions of a second interconnect layer above and adjacent to the first interconnect layer. A boundary between the first and second interconnected layers is shown by a line along A-A′. Dielectric layers 222 and 224 can be the same as dielectric layers 120 as shown in FIG. 1. Metal lines 242 and 244 can be the same as metal lines 140 as shown in FIG. 1. In some embodiments, metal lines 242 and 244 can extend along different horizontal directions. For example, as shown in FIG. 2A, metal line 242 extends along the x-axis and metal line 244 extends along the y-axis. In some embodiments, a thickness d1 of metal line 242 can be between about 5 nm and about 50 nm. In some embodiments, metal lines 242 and 244 can have similar thicknesses. In some embodiments, top surfaces of metal line 244 and dielectric layer 224 can be coplanar.

In some embodiments, structure 200 can further include an etch stop layer 230 disposed on the first interconnect layer. For example, as shown in FIG. 2A, etch stop layer 230 can be disposed on metal line 242 and under dielectric layer 224. In some embodiments, etch stop layer 230 can include one or more sublayers of low-k dielectric materials, such as SiₓO_{y}, SiₓN_{y}, SiₓO_{y}C_{z}Nᵤ, SiₓC_{y}N_{z}, SiₓO_{y}N_{z}, SiₓC_{y}, AlₓN_{y}, AlₓO_{y}, or AlₓO_{y}N_{z}. In some embodiments, a thickness of each of the sublayers of low-k dielectric materials can be between about 1 nm and about 10 nm. In some embodiments, a thickness of etch stop layer 230 can be between about 1 nm and about 50 nm.

Referring to FIG. 2A, structure 200 can further include a conductive via 250 in dielectric layer 224, through etch stop layer 230, and electrically coupling metal lines 242 and 244. Conductive via 250 can include a conductive material the same as or similar to metal lines 242 and 244, such as titanium, cobalt, aluminum, copper, tungsten, tantalum, nickel, ruthenium, other suitable metals, and/or a combination thereof. In some embodiments, conductive via 250 can include a conductive material different from that in metal line 242. In some embodiments, structure 200 can further include a barrier layer 260 surrounding conductive via 250. Barrier layer 260 can be disposed between conductive via 250 and dielectric layer 224. Barrier layer 260 can also be disposed between conductive via 250 and etch stop layer 230. Barrier layer 260 can prevent a diffusion of the conductive material from conductive via 250 into dielectric layer 224 and etch stop layer 230. In some embodiments, barrier layer 260 can also be disposed between conductive via 250 and metal line 242. In some embodiments, barrier layer 260 can include tantalum and/or tantalum nitride. In some embodiments, barrier layer 260 can have a thickness between about 0.5 nm and about 5 nm. In some embodiments, barrier layer 260 can also be disposed between metal line 244 and dielectric layer 224.

Referring to FIG. 2A, conductive via 250 can have a rivet shape and include a first portion 252 (as a head portion of the rivet shape) and a second portion 254 (as a shaft portion of the rivet shape) on first portion 252. First portion 252 can be a protrusion into metal line 242 and under line A-A′. For example, first portion 252 can extend laterally under dielectric layer 224 and etch stop layer 230. Second portion 254 can extend through etch stop layer 230 and dielectric layer 224 and is in contact with metal line 244. In some embodiments, second portion 254 can have a tapered shape with side surface 254s slanted and have a width w1 at a lower end of second portion 254 less than a width w2 at an upper end of second portion 254. In some embodiments, side surface 254s can be perpendicular to a top surface of metal line 242, with widths w1 and w2 substantially the same. In some embodiments, widths w1 and w2 can be between about 2 nm and about 50 nm.

As shown in FIG. 2A, first portion 252 of conductive via 250 can extend vertically into metal line 242. For example, a ratio of a vertical thickness d of first portion 252 to thickness d1 of metal line 242 can be between about 0.2 and about 0.7. First portion 252 can also extend laterally in metal line 242. For example, first portion 252 can have an upper surface 252u with a lateral extension w3 towards a first horizontal direction from a point 252a to a point 252b, with point 252a the position where side surface 254s of second portion 254 and upper surface 252u connect with each other. In some embodiments, first portion 252 can also extend laterally with a lateral extension w4 towards a second horizontal direction opposite to the first direction. In some embodiments, lateral extensions w3 and w4 can be substantially the same. In some embodiments, lateral extensions w3 and w4 can be different and have a variation less than about 10%. In some embodiments, lateral extension w3 and w4 can be between about 1 nm and about 100 nm. In some embodiments, a ratio between lateral extension w3 and widths w1 can be between about 0.1 and about 1. In some embodiments, a ratio between lateral extension w3 and vertical thickness d can be between about 0.5 and about 1. In some embodiments, a total width of the first portion (w1+w3+w4) can be greater than width w2. In some embodiments, first portion 252 can have a curved lower surface 252d. In some embodiments, an angle α at a point 252b can be between about 30° and about 90°, with point 252b being the position where lower surface 252d and upper surface 252u connect with each other. In some embodiments, an angle β between side surface 254s and upper surface 252u can be between about 60° and about 90°. In some embodiments, angle β can be greater than about 90°. In some embodiments, both lower surface 252d and upper surface 252u can be covered by barrier layer 260. In some embodiments, the protrusion of first portion 252 of conductive via 250 into metal line 242 can increase a contact area between conductive via 250 and metal line 242, such that influence of the relatively high resistive barrier layer 260 between conductive via 250 and metal line 242 can be adequately mitigated. In some embodiments, a ratio of a length of lower surface 252d and width w1 at lower end of second portion 254 can be between about 2 and about 10, corresponding to an enhancement of a contact conductance compared to a scenario without first portion 252.

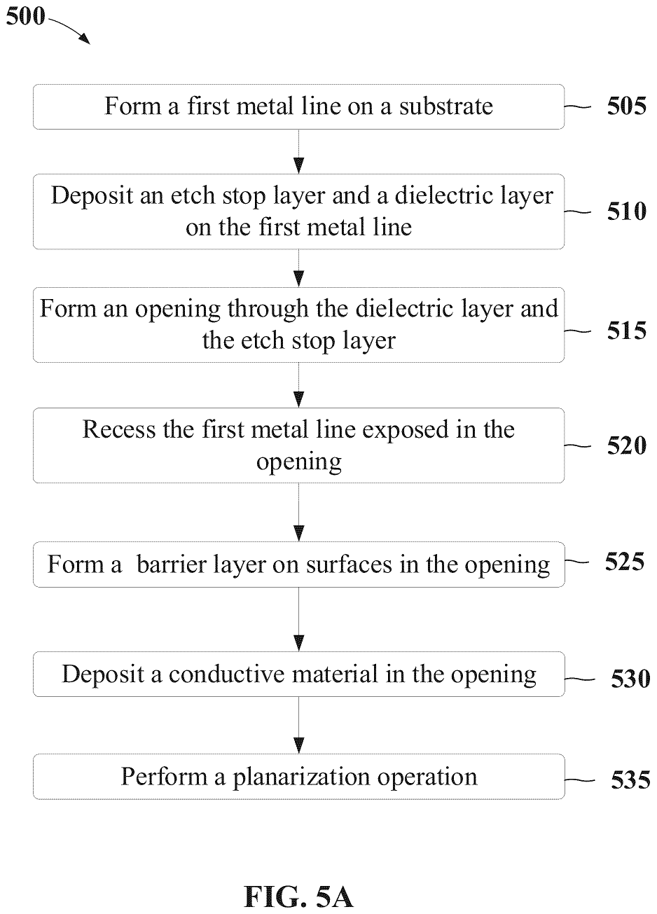

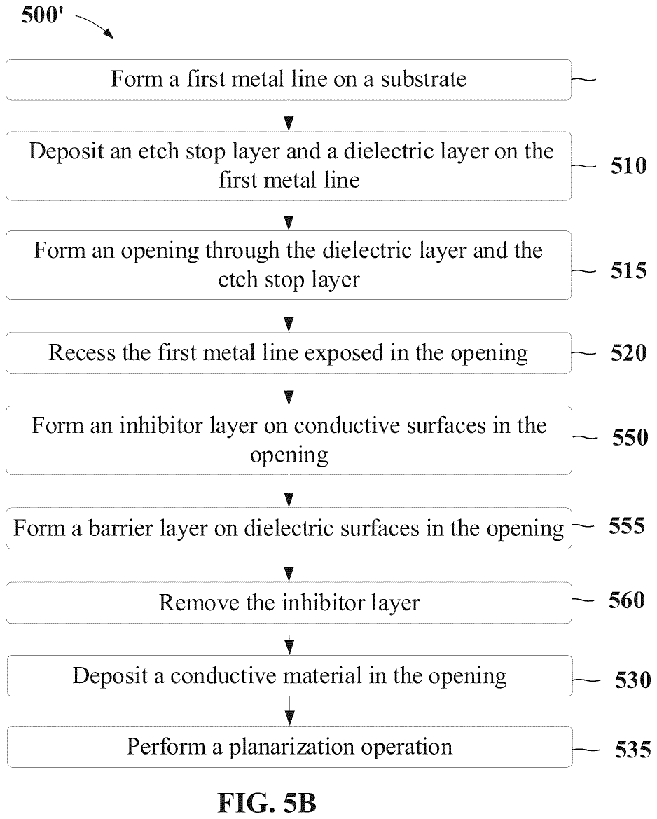

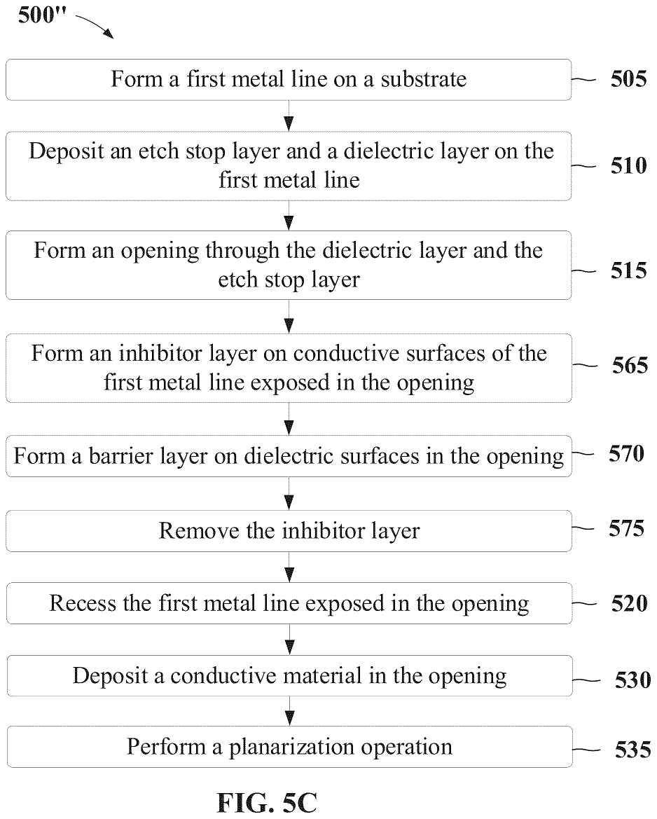

As described below with reference to methods in FIGS. 5A-5C, the rivet shape of conductive via 250 is formed by recessing metal line 242 to form a cavity under etch stop layer 230, followed by filling the cavity with the conductive material to form first portion 252 of conductive via 250. Depending on the details of the recess, first portion 252 may have different shapes. FIG. 2B illustrates another embodiment of conductive via 250 having first portion 252 with a shape different from the one in FIG. 2A. In particular, as shown in FIG. 2B, angle α between lower surface 252d and upper surface 252u can be greater than about 90°. For example, angle α can be between about 90° and about 120°. In some embodiments, having angle α greater than about 90° can further increase the contact area between conductive via 250 and metal line 242. The discussion of other elements in FIG. 2A with the same annotations applies to FIG. 2B, and is not repeated for simplicity.

In some embodiments, upper surface 252u of first portion 252 can be in contact with a bottom surface of etch stop layer 230 without being covered by barrier layer 260, and lower surface 252d of first portion 252 can have direct contact with metal line 242 without barrier layer 260 between the two, as shown in FIG. 2C. The discussion of other elements in FIGS. 2A and 2B with the same annotations applies to FIG. 2C, unless mentioned otherwise.

Referring to FIG. 2C, in some embodiments, even if conductive via 250 is in direct contact with metal line 242, the contact resistance can still affect the conductive performance of conductive via 250. This is because metal line 242 and conductive via 250 are deposited separately rather than continuously. In particular, the presence of defects/impurities on a surface of metal line 242 after it is recessed can affect the grain structure of conductive via 250 deposited on it, resulting in different grain structures on opposite sides of lower surface 252d. For example, on one side of lower surface 252d with first portion 252, average grain size of the conductive material can be less than it is on the other side of lower surface 252d with metal line 242. The structural difference between the two sides of lower surface 252d can cause a conductivity mismatch, which can affect the conductive performance of conductive via 250. With the lateral extension of first portion 252, a contact area between conductive via 250 and metal line 242 can be increased, mitigating the influence of the conductivity mismatch at lower surface 252d as a boundary between conductive via 250 and metal line 242. Although FIG. 2C shows conductive via 250 having first portion 252 with a shape similar to that in FIG. 2A (with angle α less than about 90°), it should be understood that first portion 252 in FIG. 2C can also have a shape similar to that in FIG. 2B (with angle α greater than about 90°).

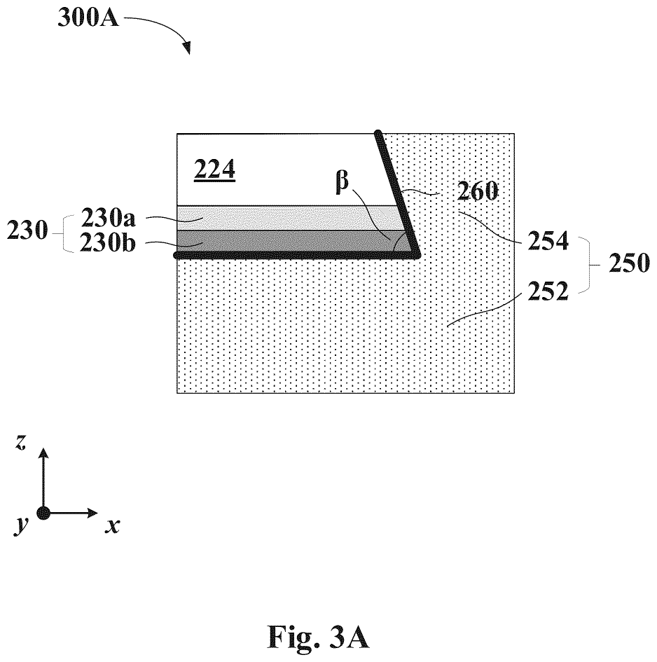

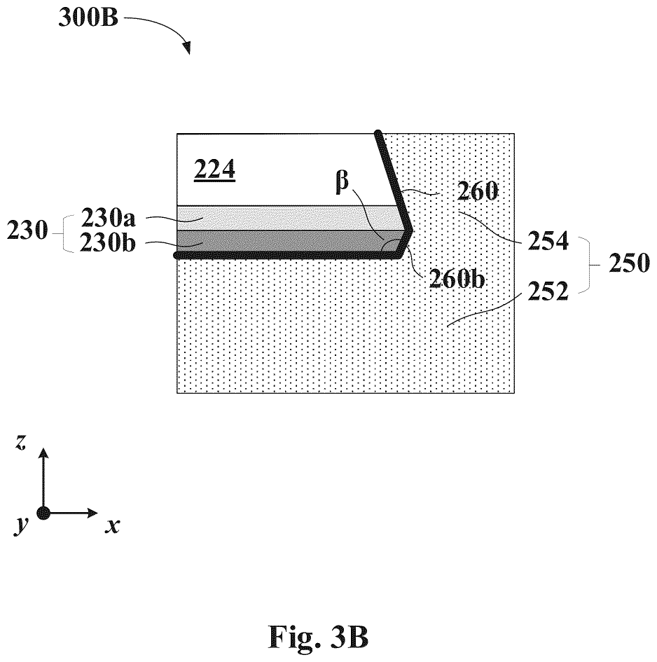

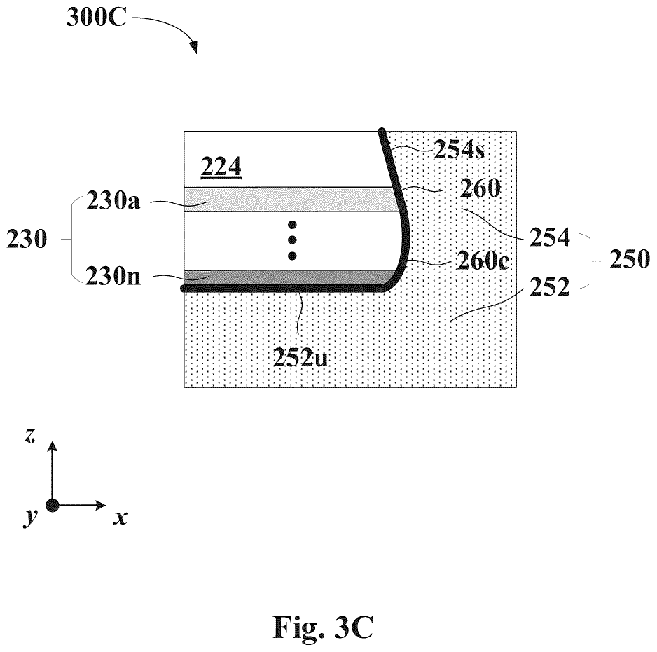

As mentioned above, etch stop layer 230 can include one or more layers of dielectric materials. In some embodiments, first and second portions 252 and 254 of conductive via 250 can connect with each other with a connection profile fine-tuned by etch stop layer 230. In particular, for etch stop layer 230 with multiple layers of dielectric material, angle β between side surface 254s of second portion 254 and upper surface 252u can be adjusted to improve the conductive performance of conductive via 250, as shown in FIGS. 3A-3C. FIGS. 3A-3C illustrate cross-sectional views of a structure 300 as a zoomed-in portion of FIGS. 2A-2C around angle β. The discussion of elements in FIGS. 2A-2C with the same or similar annotations applies to FIGS. 3A-3C, unless mentioned otherwise.

Referring to FIG. 3A, in some embodiments, etch stop layer 230 can include two sublayers 230a and 230b with different dielectric materials, and angle β can be less than about 90°.

Referring to FIG. 3B, in some embodiments, the two sublayers 230a and 230b of etch stop layer 230 can have different etching selectivities, such that during an etching process to recess metal line 242, sublayer 230b can also recessed, whereas sublayer 230a can be recessed by a lower amount. As a result, angle β can be greater than about 90°, and barrier layer 260 can include a section 260b on side surface of sublayer 230b and not aligned with the rest of barrier layer 260 disposed on dielectric layer 224.

Referring to FIG. 3C, in some embodiments, etch stop layer 230 can include a number of sublayers 230a to 230n with varying etching selectivities, such that barrier layer 260 can include a section 260c as a smooth transition of barrier layer 260 from side surface 254s of second portion 254 to the upper surface of first portion 252. As a result, angle β becomes less obvious, and side surface 254s of second portion 254 to upper surface of first portion 252 can be smoothly connected around etch stop layer 230 without an outstanding angular structure. In some embodiments, the smooth connection of the surfaces of first and second portions 252 and 254 can improve mechanical, thermal, and/or electrical performance of conductive via 250. For example, with the absence of an outstanding angular structure, first and second portions 252 and 254 can have an improved mechanical connection and be less susceptible to stress or mechanical deformation under varying conditions during a manufacturing process (such as an annealing process). The smooth profile of the surfaces of conductive via 250 can also improve its conductive performance due to the reduction of surface scattering or electrostatic charge accumulation.

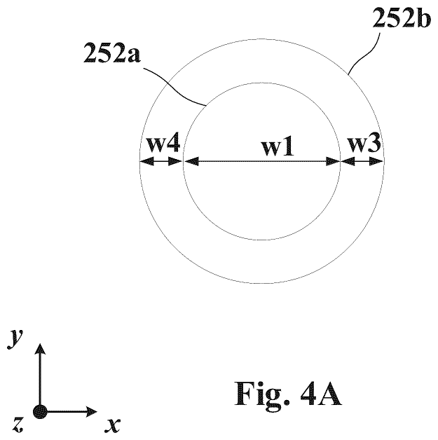

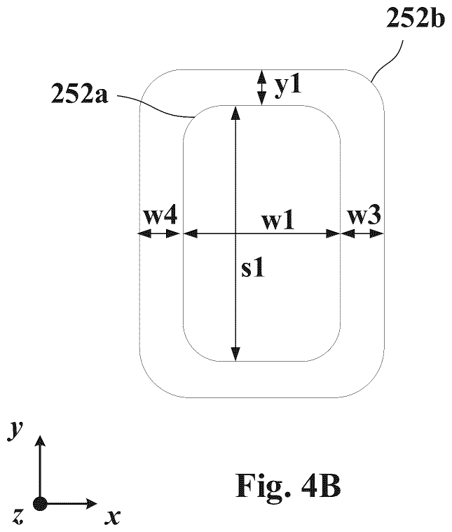

Although FIGS. 2A-3C show that first portion 252 of conductive via 250 can laterally extend along the x-axis under etch stop layer 230, in some embodiments, first portion 252 can also laterally extend along a different lateral direction (such as along the y-axis), as shown in FIGS. 4A and 4B. FIGS. 4A and 4B illustrate cross sectional views of structure 200 corresponding to line A-A′ in FIGS. 2A-2C. FIGS. 4A and 4B are from a top view perspective (along the z-axis), with lines 252a and 252b correspond to points 252a and 252b in FIG. 2A, respectively. In particular, line 252a corresponds to the line where side surface 254s of second portion 254 and upper surface 252u of first portion 252 connect with each other, and line 252a corresponds to a perimeter of the lateral extension of first portion 252 (where first portion 252 and metal line 242 meet along line A-A′).

Referring to FIG. 4A, in some embodiments, conductive via 250 can have a cylindrical symmetry, with lines 252a and 252b being circles having a same axis. In particular, a diameter w1 of line 252a is the same as width w1 as shown in FIG. 2A, and a radius of line 252b is greater than that of line 252a by a length w3 or w4, the same it is shown in FIG. 2A.

Referring to FIG. 4B, in some embodiments, conductive via 250 can have a cross section with a rectangular shape. In some embodiments, the rectangular shape can have rounded corners. For example, the lower end of second portion 254, as represented by line 252a, can have width w1 along the x-axis and length s1 along the y-axis. Similar to the lateral extensions w3/w4 of first portion 252 along the x-axis as it is shown in FIG. 2A, a lateral extension y1 of first portion 252 along the y-axis be between about 1 nm and about 100 nm. In some embodiments, lateral extension y1 can be the same as lateral extensions w3/w4. In some embodiments, lateral extension y1 can be different from lateral extensions x3/x4. In some embodiments, a ratio of lateral extensions w3/w4 or y1 to width w1 or length s1 can be between about 0.1 and about 1.

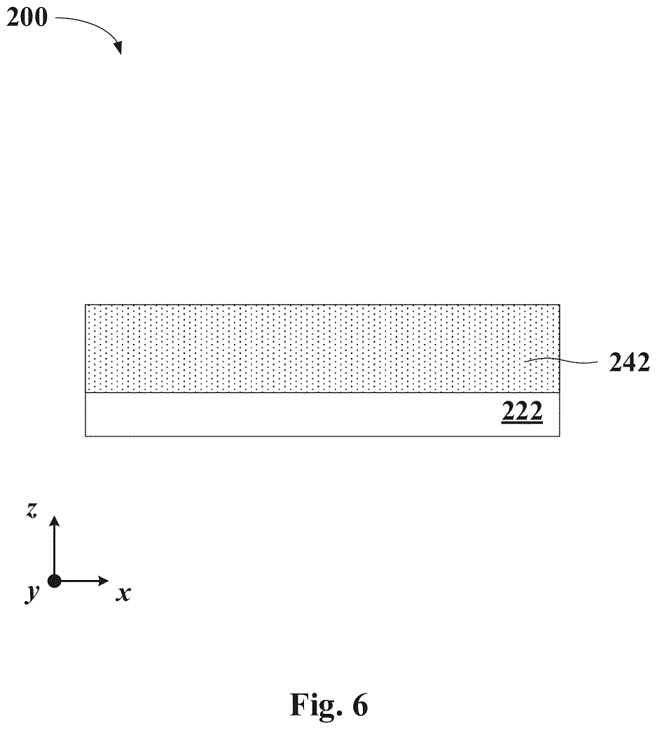

According to some embodiments, FIGS. 5A-5C illustrate flowcharts of fabrication methods 500, 500′, and 500″ for the formation of structure 200 as shown in FIGS. 2A-2C. This disclosure is not limited to this operational description and additional operations may be performed. Other fabrication operations can be performed between the various operations of methods 500, 500′, and 500″, and are omitted merely for clarity. Moreover, not all operations may be needed to perform the disclosure provided herein. Additionally, some of the operations may be performed simultaneously, or in a different order than the ones shown in FIGS. 5A-5C. In some embodiments, one or more other operations may be performed in addition to or in place of the presently described operations. For illustrative purposes, method 500 is described with reference to the structures shown in FIGS. 6-11, 2A, and 2B, method 500′ is described with reference to the structures shown in FIGS. 6-10, 12-14, and 2C, and method 500″ is described with reference to the structures shown in FIGS. 6-9, 14-17, and 2C. The discussion of elements in FIGS. 2A-2C with the same annotations applies to FIGS. 6-17, unless mentioned otherwise.

Referring to FIG. 5A, method 500 can begin with operation 505 and the process of forming a first metal line on a substrate. In some embodiments, the substrate can include a dielectric layer 222, as described with reference to FIG. 6, and forming the first metal line can include (i) forming a trench in dielectric layer 222 and extending along a horizontal direction (such as the x-axis) and (ii) depositing a conductive material in the trench to form metal line 242. In some embodiments, prior to forming first metal line 242, a device layer (such as device layer 116 as shown in FIG. 1) can be formed under dielectric layer 222. In some embodiments, forming metal line 242 can include depositing a metal, such as titanium, aluminum, copper, tungsten, tantalum, nickel, ruthenium, other suitable metals, and/or a combination thereof. In some embodiments, depositing the metal can include performing a sputtering process, an evaporation process, an electrochemical plating (ECP) process, a chemical vapor deposition (CVD) process, or an atomic vapor deposition process (ALD). For example, during the ECP process, copper can be deposited using an electrolyte such as a mixture of copper sulfate and sulfuric acid. The deposition rate and the properties of the deposited metal line 242 can be controlled by adjusting a concentration of copper sulfate in the electrolyte, a current density applied in the ECP process, a plating time, and/or a temperature of the electrolyte. In some embodiments, forming metal line 242 can include a planarization process, such as a chemical mechanical polishing (CMP) process, to form a flat top surface of metal line 242.

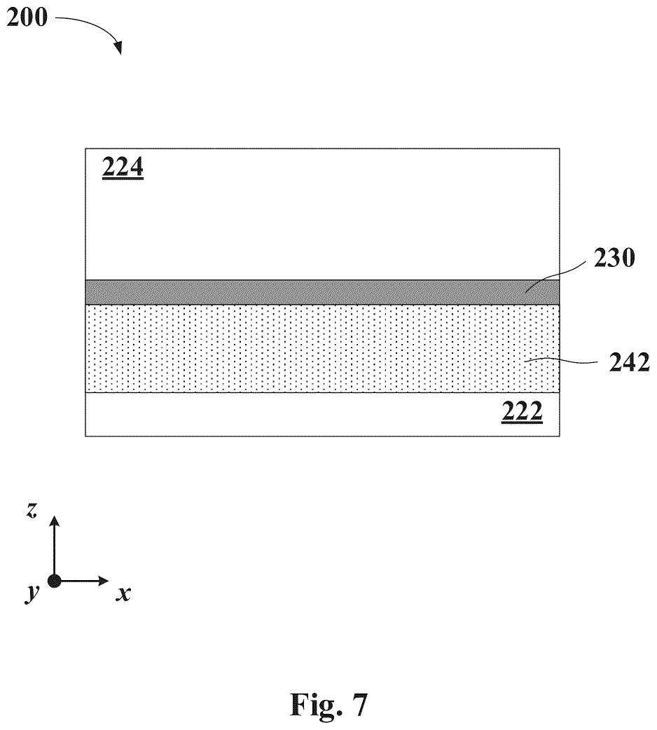

Referring to FIG. 5A, method 500 can continue with operation 510 and the process of depositing an etch stop layer and a dielectric layer on the first metal line. For example, etch stop layer 230 can be deposited over metal line 242 and dielectric layer 222, and dielectric layer 224 can be deposited over etch stop layer 230, as described with reference to FIG. 7. In some embodiments, depositing etch stop layer 230 can include blanket depositing a layer of dielectric material. In some embodiments, depositing etch stop layer 230 can include sequentially depositing a number of sublayers of different dielectric materials. In some embodiments, depositing etch stop layer 230 can include choosing dielectric materials for the sublayers according to the etching selectivities of the dielectric materials, so that a geometric profile of a subsequently formed conductive via can be tuned as described with reference to FIGS. 3A-3C. In some embodiments, etch stop layer 230 can be deposited by an ALD process, a CVD process, a plasma-enhanced CVD (PECVD) process, and/or a sputtering process.

In some embodiments, depositing dielectric layer 224 can include blanket depositing a layer of low-k dielectric material, similar to the process of depositing etch stop layer 230.

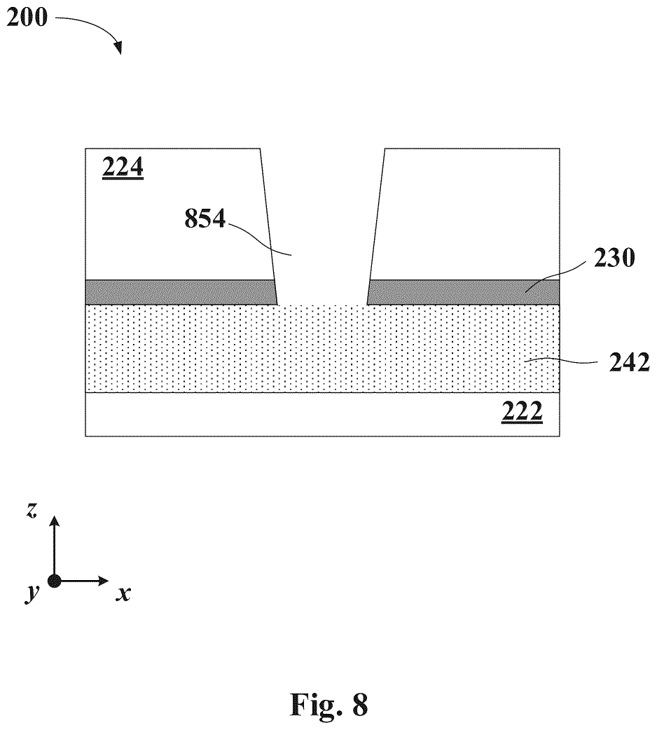

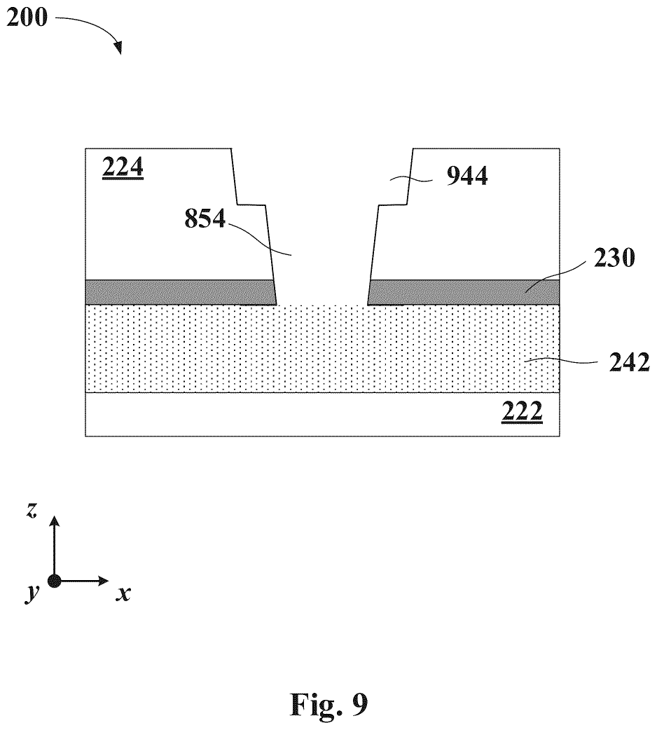

Referring to FIG. 5A, method 500 can continue with operation 515 and the process of forming an opening through the dielectric layer and the etch stop layer. For example, an opening 854 can be formed through dielectric layer 224 and etch stop layer 230, as described with reference to FIG. 8. In some embodiments, as described below, opening 854 can be filled subsequently with a conductive material to form a conductive via. In some embodiments, forming opening 854 can include (i) forming a mask on dielectric layer 224 with patterns exposing a portion of dielectric layer 224, (ii) etching the exposed portion of dielectric layer 224 to expose the etch stop layer 230, and (iii) etching through etch stop layer 230 to expose a top surface of metal line 242. In some embodiments, etching dielectric 224 and etch stop layer 230 can include a dry etching process with etchants, such as carbon fluoride (CₓF_{y}), nitrogen (N₂), carbon dioxide (CO₂), argon (Ar) and a combination thereof. In some embodiments, the etchants can be in a form of a plasma. In some embodiments, after opening 854 is formed, the mask on dielectric layer 224 can be removed. In some embodiments, after forming opening 854, a trench 944 can be formed in dielectric 224 and above opening 854, as described with reference to FIG. 9. In some embodiments, trench 944 can be formed to extend along a horizontal direction (such as the y-axis), and as described below, can subsequent be filled with a conductive material to form metal line 244 as shown in FIGS. 2A-2C.

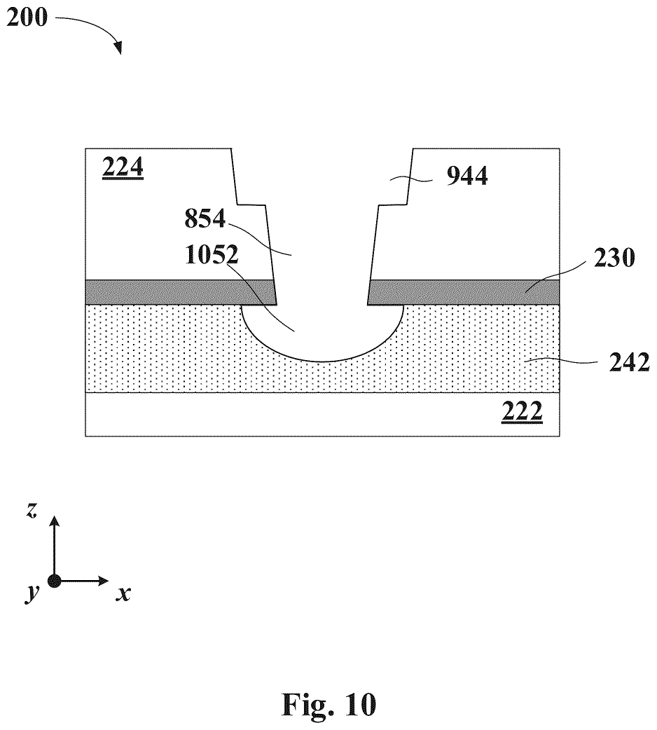

Referring to FIG. 5A, method 500 can continue with operation 520 and the process of recessing the first metal line. For example, a cavity 1052 in metal line 242 can be formed by recessing a portion of metal line 242 exposed in opening 854, as described with reference to FIG. 10. Cavity 1052 is an extension of opening 854 into metal line 242. Cavity 1052 can be formed to have a shape of a rivet head extending laterally and vertically into metal line 242. Cavity 1052 can also be formed to extend in different lateral directions (such as along the x-axis and y-axis) in metal line 242. As described below, cavity 1052 and opening 854 can subsequent be filled with a conductive material to form first and second portions 252 and 254 of conductive via 250 as shown in FIG. 2A-2C.

In some embodiments, recessing metal line 242 can include performing a selective isotropic etching operation in opening 854, such as a wet etching operation that can selectively etch the conductive material of metal line 242 without etching the dielectric materials of dielectric layer 224 and/or etch stop layer 230. The wet etching operation can include etching with an etchant that can etch metals isotropically, such that cavity 1052 can be extended both laterally and vertically into metal line 242. In some embodiments, the etchant can include a chemical solution for etching copper, such as ferric chloride, ammonium persulfate, nitric acid, copper dichloride, and a combination thereof. The etchant can oxidize the copper surface, which then dissolves in the chemical solution. The etching conditions can be controlled according to the desired geometry of cavity 1052 and the specific etchant being used. In some embodiments, a temperature of the chemical solution can be adjusted to control an etching rate of metal line 242. For example, the wet etching operation can be conducted at room temperature or at elevated temperatures. In some embodiments, a width and/or a depth of cavity 1052 can be controlled by an etching time. In some embodiments, sublayers of etch stop layer 230 can be also etched (at a lower etching rate compared with the etching rate of metal line 242) in the wet etching operation, and a geometric profile of a side surface of etch stop layer 230 can be fine-tuned, as described with reference to FIGS. 3A-3C, by choosing proper options of etchants and controlling the etching time.

In some embodiments, recessing metal line 242 can include performing an etching operation that combines wet and dry etchings. For example, an anisotropic dry etching can be used at first to extend opening 854 deep into metal line 242 by etching metal line 242 only in the vertical direction, and then the selective isotropic wet etching can be used to form cavity 1052 by recessing metal line 242 laterally. The anisotropic dry etching can be the same as or similar to the dry etching process in operation 515 to form opening 854. In some embodiments, with metal line 242 already recessed vertically after the anisotropic dry etching, the wet etching can start at a depth under the upper surface of metal line 242, and in addition to recessing metal line 242 laterally and vertically downward, the wet etching can also recess metal line 242 vertically upward to form a cavity having a geometry similar to first portion 252 of conductive via 250 as shown in FIG. 2B (with angle α greater than about 90°).

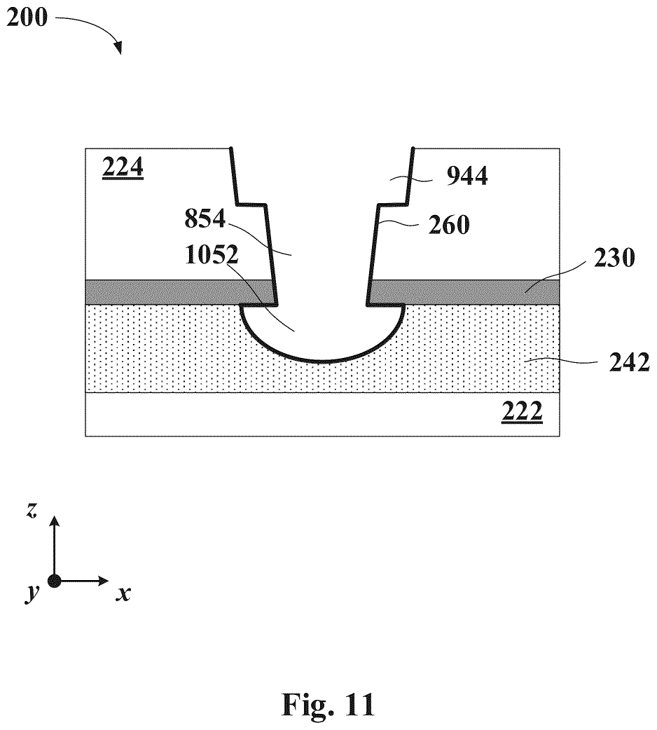

Referring to FIG. 5A, method 500 can continue with operation 525 and the process of forming a barrier layer in the opening. For example, barrier layer 260 can be formed over surfaces of opening 854 and cavity 1052, as described with reference to FIG. 11. For example, barrier layer 260 can be formed on side surfaces of dielectric layer 224 and etch stop layer 230. In some embodiments, barrier layer 260 can be formed under dielectric layer 224 and on a bottom surface of etch stop layer 230. In some embodiments, barrier layer 260 can be formed on a curved surface of metal line 242 exposed in cavity 1052. In some embodiments, barrier layer 260 can also be formed over surfaces of trench 944. In some embodiments, forming barrier layer 260 can include depositing a layer of tantalum and/or tantalum nitride by a PVD process, a CVD process, or an ALD process. In some embodiments, the layer of tantalum and/or tantalum nitride can be deposited by using tantalum chloride (TaCl₅) and ammonia (NH₃) as precursors. In some embodiments, forming barrier layer 260 can include a post deposition annealing operation to improve an adhesion of the layer of tantalum and/or tantalum nitride on surfaces of opening 854 and cavity 1052.

Referring to FIG. 5A, method 500 can continue with operation 530 and the process of depositing a layer of conductive material in the opening. For example, conductive via 250 can be formed by depositing a metal in opening 854 and cavity 1052, as described with reference to FIG. 11 and FIGS. 2A and 2B. In some embodiments, depositing the metal in opening 854 and cavity 1052 can be the same as or similar to forming metal line 242 in operation 505. For example, copper can be deposited in opening 854 and cavity 1052 by an ECP process. In some embodiments, barrier layer 260 can be used as a seed layer to facilitate the deposition of copper in the ECP process. During the ECP process, copper can be deposited using an electrolyte such as a mixture of copper sulfate and sulfuric acid. The deposition rate and the properties of conductive via 250 can be controlled by adjusting a concentration of copper sulfate in the electrolyte, a current density applied in the ECP process, a plating time, and/or a temperature of the electrolyte. In some embodiments, after forming conductive via 250, the ECP process can be continued to form metal line 244 on conductive via 250.

Referring to FIG. 5A, method 500 can continue with operation 535 to perform a planarization operation on metal line 244 and dielectric layer 224, as described with reference to FIGS. 2A and 2B. In some embodiments, the planarization process can include a CMP process to form coplanar top surfaces of metal line 244 and dielectric layer 224. In some embodiments, planarizing the top surfaces of metal line 244 and dielectric layer 224 can facilitate fabricating subsequent structures on metal line 244 and dielectric layer 224, such as further conductive vias and metal lines formed in subsequent BEOL processes similar to and electrically connected to metal lines 242 and 244 and conductive via 250.

Referring to FIG. 5B, method 500′ can be used to form structure 200 as described with reference to FIG. 2C. Compared to method 500 in FIG. 5A, method 500′ can include the same operations 505-520, 530, and 535 as method 500. However, operation 525 of method 500 is replaced by operations 550-560 in method 500′. In the following description of method 500′, the descriptions for operations 505-520, 530, and 535 and the corresponding FIGS. 6-10 are not repeated in detail for simplicity.

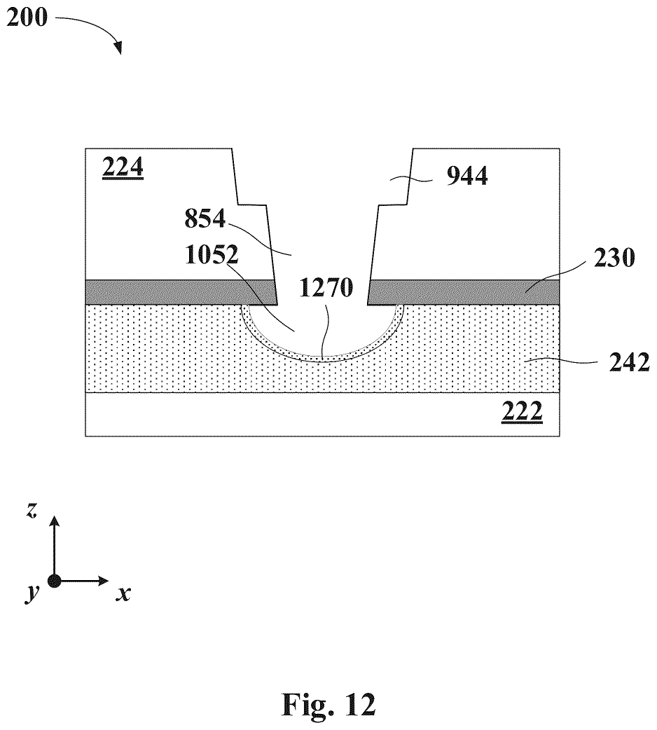

Referring to FIG. 5B, after operation 520 that forms intermediate structure 200 as described with reference to FIG. 10, method 500′ can continue with operation 550 and the process of forming an inhibitor layer on conductive surfaces in the opening. For example, an inhibitor layer 1270 can be formed on a surface of metal line 242 exposed in cavity 1052, as described with reference to FIG. 12. Inhibitor layer 1270 can be selectively deposited on conductive surfaces but not on non-conductive surfaces (e.g., dielectric surfaces of dielectric layer 224 and etch stop layer 230) and can inhibit the subsequently formed barrier layer from depositing on the surface of metal line 242. In some embodiments, forming inhibitor layer 1270 can include depositing quaternary ammonium cation, benzotriazole, tolyltriazole, and/or 5,6-dimethyl benzotriazol by a physical adsorption process, a chemical adsorption, and/or an electrostatic adsorption process.

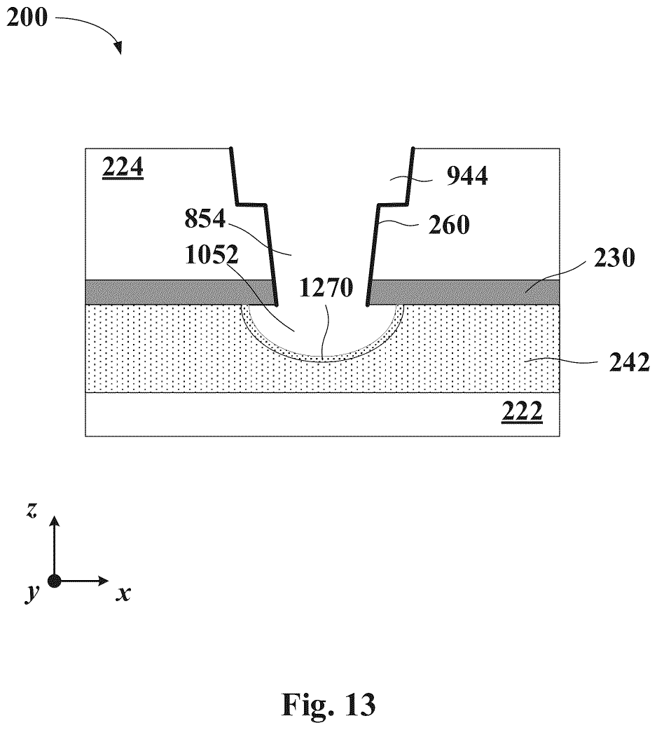

Referring to FIG. 5B, method 500′ can continue with operation 555 and the process of forming a barrier layer on dielectric surfaces in the opening. The description of forming the barrier layer in operation 525 applies to forming the barrier layer in operation 555, unless mentioned otherwise. For example, barrier layer 260 can be formed on side surfaces of dielectric layer 224 and etch stop layer 230 exposed in opening 854 and/or trench 944, as described with reference to FIG. 13. In some embodiments, the presence of inhibitor layer 1270 can prevent the formation of barrier layer 260 on an upper surface of inhibitor layer 1270 exposed in cavity 1052.

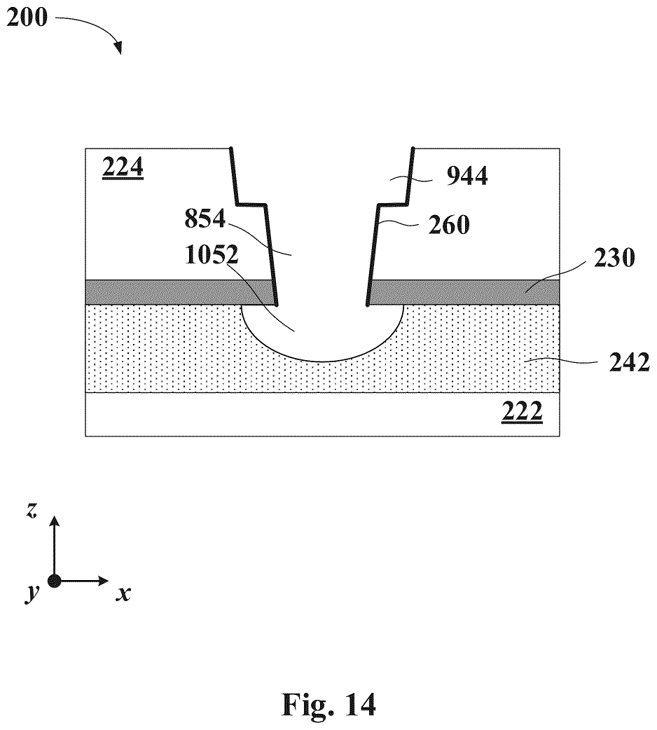

Referring to FIG. 5B, method 500′ can continue with operation 560 and the process of removing the inhibitor layer. For example, inhibitor layer 1270 in FIG. 13 can be removed to expose the surface of metal line 242 in cavity 1052, as described with reference to FIG. 14. In some embodiments, removing inhibitor layer 1270 can include treating intermediate structure 200 as shown in FIG. 13 with plasma by exposing intermediate structure 200 to a plasma gas, such as hydrogen, oxygen, nitrogen, argon, and/or a combination thereof. For example, inhibitor layer 1270 can be release from the surface of metal line 242 when exposed to a plasma.

Referring to FIG. 5B, method 500′ can continue with operations 530 and 535 to form structure 200 as shown in FIG. 2C. The description of operations 530 and 535 as provided in the discussion of method 500 is not repeated for simplicity.

Referring to FIG. 5C, method 500″ can be used to form structure 200 as described with reference to FIG. 2C. Compared to method 500 in FIG. 5A, method 500′ can include the same operations 505-520, 530, and 535 as method 500. However, in method 500″, additional operations 565-575 are introduced between operations 515 and 520. In the following description of method 500″, the descriptions for operations 505-520, 530, and 535 and the corresponding FIGS. 6-9 and 14 are not repeated in detail for simplicity.

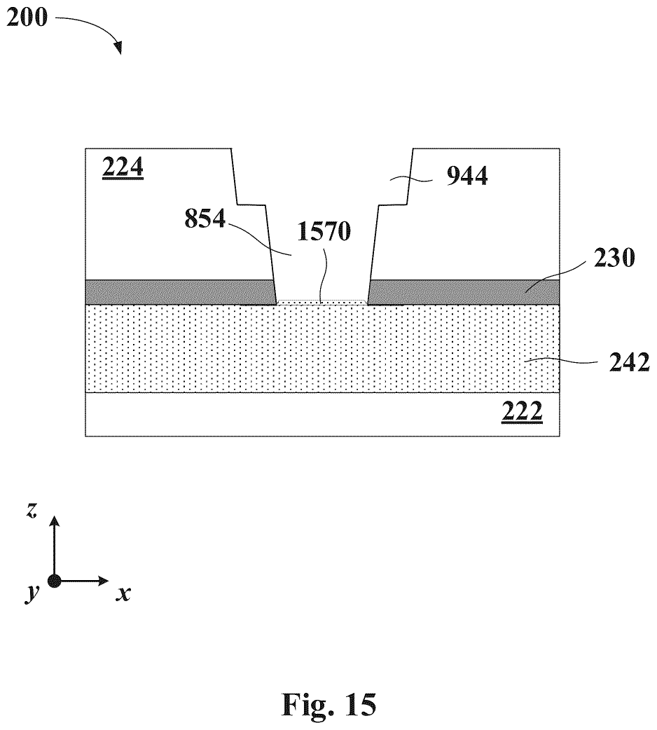

Referring to FIG. 5C, after operation 515 that forms the opening through the dielectric layer and the etch stop layer, as described with reference to FIG. 9, method 500″ can continue with operation 565 and the process of forming an inhibitor layer on conductive surfaces in the opening. For example, an inhibitor layer 1570 can be formed on a surface of metal line 242 exposed in opening 854, as described with reference to FIG. 15. Inhibitor layer 1570 can be selectively deposited on conductive surfaces but not on non-conductive surfaces (e.g., dielectric surfaces of dielectric layer 224 and etch stop layer 230) and can inhibit the subsequently formed barrier layer from depositing on the surface of metal line 242. In some embodiments, forming inhibitor layer 1570 can include depositing quaternary ammonium cation, benzotriazole, tolyltriazole, and/or 5,6-dimethyl benzotriazol by a physical adsorption process, a chemical adsorption, and/or an electrostatic adsorption process.

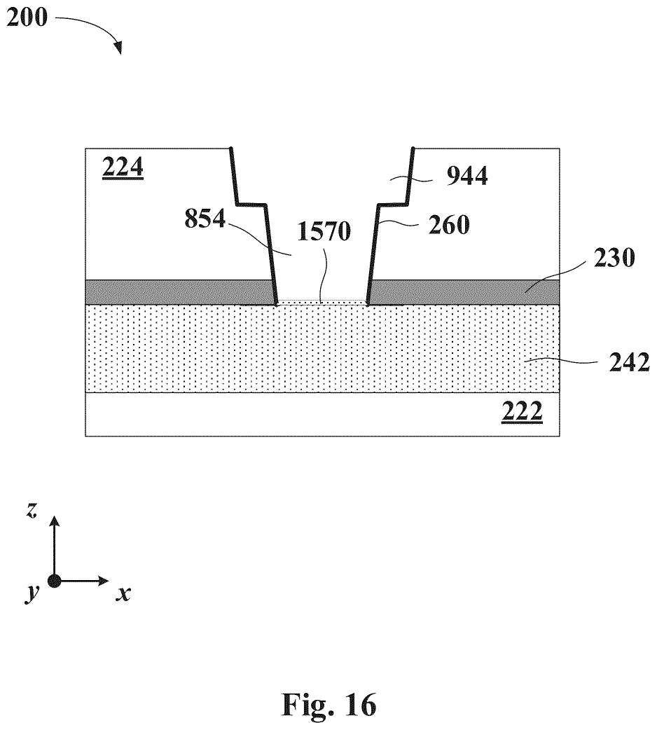

Referring to FIG. 5C, method 500″ can continue with operation 570 and the process of forming a barrier layer on dielectric surfaces in the opening. The description of forming the barrier layer in operation 525 applies to forming the barrier layer in operation 570, unless mentioned otherwise. For example, barrier layer 260 can be formed on side surfaces of dielectric layer 224 and etch stop layer 230 exposed in opening 854 and/or trench 944, as described with reference to FIG. 16. In some embodiments, the presence of inhibitor layer 1570 can prevent the formation of barrier layer 260 on an upper surface of inhibitor layer 1570 exposed in opening 854.

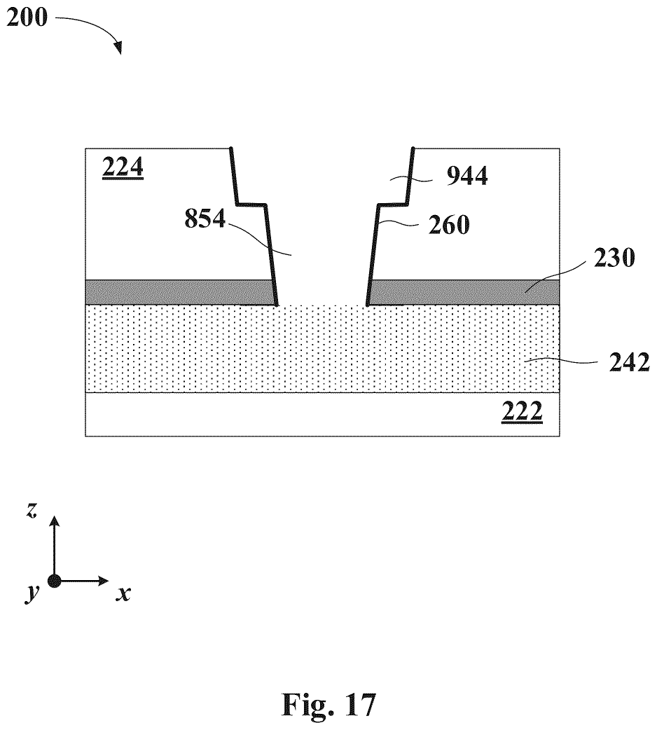

Referring to FIG. 5C, method 500″ can continue with operation 575 and the process of removing the inhibitor layer. For example, inhibitor layer 1570 in FIG. 16 can be removed to expose the surface of metal line 242 in opening 854, as described with reference to FIG. 17. In some embodiments, removing inhibitor layer 1570 can include treating intermediate structure 200 as shown in FIG. 16 with plasma by exposing intermediate structure 200 to a plasma gas, such as hydrogen, oxygen, nitrogen, argon, and/or a combination thereof. For example, inhibitor layer 1570 can be release from the surface of metal line 242 when exposed to a plasma.

Referring to FIG. 5C, method 500′ can continue with operation 520 to form structure 200 as shown in FIG. 14 and then with operations 530 and 535 to form structure 200 as shown in FIG. 2C. The description of operations 520, 530, and 535 as provided in the discussion of method 500 is not repeated for simplicity.

The embodiments described herein are directed to an interconnect structure of a semiconductor device and a method of forming the interconnect structure. The interconnect structure includes a first metal line, a second metal line on the first metal line, and a conductive via electrically coupling the first and second metal lines. The conductive via includes a protrusion laterally and vertically extending into the first metal line to reduce a contact resistance between the conductive via and the first metal line. The method includes forming the first metal line and a dielectric layer on the first metal line, forming an opening in the dielectric layer to expose the first metal line, and laterally recessing the first metal line in the opening. The method further includes depositing a conductive material in the opening to form the conductive via and the second metal line.

In some embodiments, a structure includes a substrate, a first metal line over the substrate, a dielectric layer on the first metal line, a second metal line in the dielectric layer, and a conductive via electrically coupling the first and second metal lines. The conductive via includes a protrusion laterally extending into the first metal line and a barrier layer surrounding protrusion.

In some embodiments, a structure includes a first metal line on a substrate, an etch stop layer on the first metal line, a dielectric layer on the etch stop layer, a conductive via in the dielectric layer and through the etch stop layer, and a second metal line on the conductive via and electrically coupled to the first metal line. The conductive via includes a first portion in the first metal line and under the etch stop layer, a barrier layer surrounding the first portion, and a second portion on the first portion. A width of the second portion is less than a width of the first portion.

In some embodiments, a method includes forming a first metal line on a substrate, depositing a dielectric layer on the first metal line, forming an opening in the dielectric layer, and recessing the first metal line in the opening in lateral and vertical directions. The method further includes forming a barrier layer on surfaces of the opening, depositing a conductive material in the opening to form a conductive via, and forming a second metal line on the conductive via.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

1. A structure, comprising:
a substrate;
a first metal line over the substrate;
a dielectric layer on the first metal line;
a second metal line in the dielectric layer; and
a conductive via electrically coupling the first and second metal lines, wherein the conductive via comprises a protrusion laterally extending into the first metal line.

2. The structure of claim 1, wherein the protrusion comprises an upper surface extending laterally under the dielectric layer.

3. The structure of claim 2, wherein a ratio of a horizontal extension of the protrusion and a width of a portion of the conductive via in the dielectric layer is between about 0.1 and about 1.

4. The structure of claim 2, wherein a width of the upper surface of the protrusion is between about 1 nm and about 100 nm.

5. The structure of claim 1, further comprising a barrier layer surrounding the conductive via.

6. The structure of claim 5, wherein the barrier layer comprises tantalum nitride.

7. The structure of claim 1, wherein the conductive via comprise copper.

8. A structure, comprising:
a first metal line on a substrate;
an etch stop layer on the first metal line;
a dielectric layer on the etch stop layer;
a conductive via in the dielectric layer and through the etch stop layer, wherein the conductive via comprises:
a first portion in the first metal line and under the etch stop layer;
a barrier layer surrounding the first portion; and
a second portion on the first portion, wherein a width of the second portion is less than a width of the first portion; and
a second metal line on the conductive via and electrically coupled to the first metal line.

9. The structure of claim 8, wherein an angle between a horizontal surface of the first portion and a side surface of the second portion is less than about 90°.

10. The structure of claim 8, wherein the first metal line and the conductive via comprise a same conductive material.

11. The structure of claim 8, wherein the barrier layer comprises a horizontal portion between the first portion and the etch stop layer.

12. The structure of claim 8, wherein the etch stop layer comprises first and second sublayers, wherein the first sublayer comprises a first dielectric material, and wherein the second sublayer comprises a second dielectric material different from the first dielectric material.

13. The structure of claim 8, wherein the first and second metal lines are in different layers of a back-end-of-line (BEOL) interconnect structure.

14. A method, comprising:
forming a first metal line on a substrate;
depositing a dielectric layer on the first metal line;
forming an opening in the dielectric layer;
recessing, in the opening, the first metal line in lateral and vertical directions;
forming a barrier layer on surfaces of the opening;
depositing a conductive material in the opening to form a conductive via; and
forming a second metal line on the conductive via.

15. The method of claim 14, wherein depositing the conductive material comprises performing an electrochemical plating operation to deposit copper in the opening.

16. The method of claim 14, wherein recessing the first metal line comprises isotropically etching the first metal line to form a cavity in the first metal line, and wherein the cavity has a rivet head shape.

17. The method of claim 14, wherein recessing the first metal line comprises etching the first metal line in a first lateral direction and a second lateral direction different from the first lateral direction.

18. The method of claim 14, wherein forming the barrier layer comprises depositing tantalum nitride.

19. The method of claim 14, wherein forming the barrier layer comprises depositing the barrier layer under the dielectric layer.

20. The method of claim 14, further comprising forming an etch stop layer on the first metal line, wherein forming the barrier layer comprises depositing the barrier layer on a bottom surface of the etch stop layer.
